(19) United States
(12) Patent Application Publication
(10) Pub. No.: US 2025/0019505 A1
(43) Pub. Date: Jan. 16, 2025

(54) BIODEGRADABLE COMPOSITE MATERIAL

(71) Applicant: CTK RESEARCH AND DEVELOPMENT CANADA LTD., Surrey (CA)

(72) Inventors: Jitendra Panda, Surrey (CA); Saeid Tajbakhsh, Surrey (CA); Carlos Diaz

(73) Assignee: CTK Research and Development Canada Ltd., Surrey, BC (CA)

(21) Appl. No.: 18/711,833

(22) PCT Filed: Sep. 13, 2022
(86) PCT No.: PCT/CA2022/051363

§ 371 Date: May 20, 2024

Related U.S. Application Data
(60) Provisional application No. 63/281,349, filed on Nov. 19, 2021.

(51) Int. Cl. C08J 5/04; C08J 5/06; C08J 5/10; C08L 1/12; H05K 1/03

(52) U.S. Cl. CPC C08J 5/045; C08J 5/06; C08J 5/10; C08L 1/12; H05K 1/0366; C08J 2301/12; C08J 2467/02; C08L 2201/02; C08L 2201/06; H05K 2201/012; H05K 2201/029

(57) ABSTRACT

The present invention provides biodegradable composite materials comprising: a) a polymeric matrix comprising about 50-80% by weight of a cellulose alkanoate; about 0.1 to 10% by weight of a polyester, wherein the polyester is an aliphatic-aromatic copolyester, an aliphatic polyester, or a mixture of an aliphatic polyester and thermoplastic starch; about 10 to 20% by weight of a plasticizer; about 10 to 20% by weight of a flame-retardant component; optionally an inorganic filler; and b) a fibrous reinforcement material.

### FIELD OF THE INVENTION

The present invention pertains to the field of biodegradable polymeric material. In particular, it relates to biodegradable polymer-based composites as a substrate for printed circuit boards (PCB).

### BACKGROUND OF THE INVENTION

With the global generation of electronic waste (e-waste) growing at a steady rate of 3-5% each year, there is a pressing need to improve the recycling of this type of waste material after its end of life. It is estimated that more than 53 million tons of electronic waste were generated in 2019 [1]. A big portion of electronic waste comes from printed circuit boards (PCB), the framework that provides support and connection to all electronic devices. Normally, PCBs are generally composed of composite materials comprising epoxy resins and glass fibers, electronic components and certain additives that when not disposed properly, can leak heavy metals as well as toxic organic and inorganic pollutants in the environment [2, 3].

Attempts have been made to recycle PCBs, first by separating the electronic components from the board material. The most common option is to break apart the PCBs and recover the metallic fraction using magnetic sorting. The recycling of the composite material focuses mainly in the recovery of valuable metals, leaving a non-metallic fraction that normally ends up in the landfill [4]. Curing/cross linking agents used in Epoxy based PCBs are typically acids and anhydrides, which can be very toxic for land and aquatic life. The other components constitute the organic fraction of PCBs (mostly epoxy resin and additives) which is not biodegradable and can therefore generate a huge environmental pollution burden [5].

Biodegradable composite materials that can be used in the formation of parts of PCBs (such as insulating materials and substrate) are limited by compatibility with the device and fabrication process, which necessitates consideration around thermal stability, solvent compatibility and mechanical robustness of the material. Some of the key considerations are: flame retardance (critical for UL qualification), higher glass transition temperatures (Tg) (to withstand higher temperature assembly processing), mechanical strength (including shear, tensile and other mechanical attributes that may be required of the PCB when placed into service), thermal performance, and dimensional stability during manufacturing, thermal cycles or exposure to humidity.

Recent efforts towards a sustainable approach for the manufacturing of PCBs have led to fully or partially biobased composite materials. One example is paper-based matrices with excellent biodegradability, but with limited applications due to its intrinsic high moisture absorption [6-7].

PCBs have been produced from substrate sheets that include at least one biodegradable polymer, such as polyglycolic acid, polyhydroxy alkanoates, polyhydroxy butyrate, polybutylene adipate terephthalate, polybutylene succinate, polyvinyl alcohol, polylactic acid, polyhydroxy butyrate, poly(3-hydroxypropanoic acid), cellulose diacetate, cellulose acetate butyrate, cellulose acetate propionate or any combination thereof.

There is still a need for developing more sustainable bio-based, biodegradable alternatives to traditional glass epoxy PCBs that can minimize pollution of the environment after adequate recycling of the material.

### SUMMARY OF THE INVENTION

An object of the present invention is to provide a biodegradable composite material for use as the insulating substrate in printed circuit boards (PCB).

In accordance with an aspect of the present invention, there is provided a biodegradable composition comprising: about 50 to 80% by weight of a cellulose alkanoate; about 0.1 to 10% by weight of a polyester, wherein the polyester is an aliphatic-aromatic copolyester, an aliphatic polyester, or a mixture of an aliphatic polyester and thermoplastic starch; about 10 to 30% by weight of a plasticizer; about 10 to 20% by weight of a flame-retardant component; and optionally an inorganic filler.

In accordance with an aspect of the present invention, there is provided a biodegradable composite material, which comprises a) a polymeric matrix comprising: about 50-80% by weight of a cellulose alkanoate, about 0.1 to 10% by weight of a polyester, wherein the polyester is an aliphatic-aromatic copolyester, an aliphatic polyester, or a mixture of an aliphatic polyester and thermoplastic starch; about 10 to 30% by weight of a plasticizer; about 10 to 20% by weight of a flame-retardant component; optionally an inorganic filler; and b) a fibrous reinforcement material.

In accordance with an aspect of the present invention, there is provided a process for preparing a biodegradable composite as described herein. The process comprise a) admixing the cellulose alkanoate, polyester, plasticizer, flame retardant, and optionally the inorganic filler, and heating the admixture to form a blended material; and b) compression molding the blended material with the reinforcement material

### BRIEF DESCRIPTION OF THE FIGURES

The invention will now be described by way of an exemplary embodiment with reference to the accompanying figures, wherein:

FIG. 1 is a photograph of the molded composite material composed of cellulose acetate (CA), polybutylene adipate terephthalate (PBAT), limestone, melamine phosphate and 1 layer of hemp fabric. Thickness of the sample is 3.5 mm.

FIG. 2 is a photograph of the test specimens of molded composite material composed of cellulose acetate (CA), polybutylene adipate terephthalate (PBAT), limestone, melamine phosphate and 1 layer of hemp fabric after a 50 W vertical burn test (front view).

FIG. 3 is a photograph of the test specimens of molded composite material composed of cellulose acetate (CA), polybutylene adipate terephthalate (PBAT), limestone, melamine phosphate and 1 layer of hemp fabric after a 50 W vertical burn test (side view).

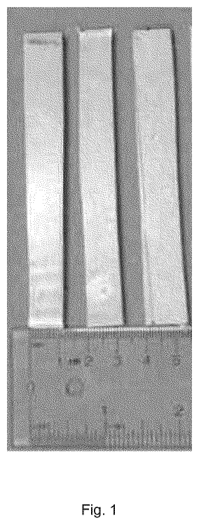

### DETAILED DESCRIPTION OF THE INVENTION

Unless defined otherwise, all technical and scientific terms used herein have the same meaning as commonly understood by one of ordinary skill in the art to which this invention belongs.

The articles “a” and “an” are used herein to refer to one or to more than one (i.e., to at least one) of the grammatical object of the article. By way of example, “an element” means one element or more than one element.

As used herein, the term “about” refers to a +/−10% variation from the nominal value. It is to be understood that such a variation is always included in a given value provided herein, whether or not it is specifically referred to.

As used herein, the term “alkanoate” refer to a group —O—(O)C—R, wherein R is C1-C6 alkyl.

As used herein, the term “alkyl” refers to a straight chain or branched alkyl group of one to ten carbon atoms unless otherwise specified. This term is further exemplified by such groups as methyl, ethyl, n-propyl, i-propyl, n-butyl, t-butyl, i-butyl, hexyl and the like.

As used herein, the term “aryl” refers to an aromatic carbocyclic group having at least one aromatic ring (e.g., phenyl) or multiple condensed rings in which at least one ring is aromatic, (e.g., naphthyl, anthryl, phenanthryl, etc.).

As used herein, the term, the term “phthalate” refers to an alky or aryl ester of phthalic acid.

As used herein, the term “tartrate” refers to an alky or aryl ester of tartaric acid.

As used herein, the term “thermoplastic starch” (TP starch) refers to starch blended with suitable plasticizer(s).

As used herein, the term “biodegradable” refers to a material that breaks down upon exposure to sunlight, water, microorganisms such as bacteria and fungi, enzymes or wind abrasion.

In one aspect, the present invention provides novel compositions for the making biodegradable composites that can be used as the insulating substrate in printed circuit boards (PCB).

The composites of the present invention exhibit excellent flame-retardant properties with V-0 or V-1 rating according to the UL-94 rating, making them a suitable alternative for their use in the making of the insulating substrate in PCBs.

The composition of the present invention comprises a cellulose alkanoate, an aliphatic polyester and/or an aliphatic-aromatic copolyester, a plasticizer, a flame-retardant compound, and optionally an inorganic filler.

In some embodiments, the composition of the present invention comprises about 50 to about 80% by weight of a cellulose alkanoate, about 0.1 to about 10% by weight of a polyester, wherein the polyester is an aliphatic-aromatic copolyester or an aliphatic polyester, about 10 to about 30% by weight of a plasticizer, about 10 to about 20% by weight of a flame-retardant component; and optionally about 0.1 to about 10% by weight of an inorganic filler.

In another aspect, the present invention provides biodegradable composites formed from a mixture of a cellulose alkanoate, an aliphatic polyester and/or an aliphatic-aromatic copolyester, a plasticizer, a flame-retardant compound and optionally an inorganic filler.

In another aspect, the present invention provides, a composite material comprising a polymeric matrix comprising cellulose alkanoate, an aliphatic polyester and/or aliphatic-aromatic copolyester, a plasticizer, a flame-retardant compound and optionally an inorganic filler, and a fibrous reinforcement material.

In some embodiments, the composite comprises about 50 to about 80% by weight of a cellulose alkanoate, about 0.1 to about 10% by weight of a polyester, wherein the polyester is an aliphatic-aromatic copolyester or an aliphatic polyester, about 10 to about 20% by weight of a plasticizer, about 10 to about 30% by weight of a flame-retardant component; and optionally about 0.1 to about 10% by weight of an inorganic filler, and a fibrous reinforcement material.

The fibrous reinforcement material can be provided in a one-dimensional, two-dimensional or three-dimensional form.

The one dimensional form is linear long fibers. The fibers may be discontinuous or continuous. The fibers may be arranged randomly or as continuous filaments parallel to each other. A fiber is defined by its aspect ratio, which is the ratio between length and diameter of the fiber. In some embodiments, fibers have an aspect ratio of at least 1000, at least 1500, at least 2000, at least 3000 or at least 5000.

The two dimensional form includes fibrous mats or non-woven reinforcements, roved, woven or bundles of fibers.

The three-dimensional form includes stacked or folded fibrous mats or non-woven reinforcements or bundles of fibers or mixtures thereof.

In an embodiment, the fibrous reinforcement material is firmed from natural fibers. Natural fibers can be vegetable/fruit fibers, leaf fibers, bast fibers, stalk fibers and/or wood fibers. Non limiting examples of natural fibers include hemp, flax, sisal, kenaf, abaca, jute, cotton, coconut (coir), banana fibers, wheat straw, rice straw, barley straw, bamboo, kapok, papyrus, ramie, hardwood pulp, softwood pulp, wood fiber, etc.

In some embodiments, the fibrous reinforcement material is a woven material made of linen, hemp or jute fibers. In some embodiments, the woven material is a plain weave or a twill weave.

In some embodiments, the composite material comprises one or more layers of a woven fabric made of natural fibers.

In some embodiments, the fabric is made of hemp fibers.

The cellulose alkanoates used in the composition of the present invention can be mono-, bi- or tri-alkanoates of cellulose. In some embodiments, the cellulose alkanoate is cellulose acetate, cellulose diacetate or cellulose triacetate.

Non-limiting examples of aliphatic polyester include polybutylene succinate (PBS), polylactic acid (PLA), and polyhydroxyalkanoates (PHA). A non-limiting examples of the aliphatic-aromatic copolyester includes polybutylene adipate terephthalate (PBAT).

In some embodiments, a fraction of aliphatic polyester can be replaced by thermoplastic starch (TPS), which is a starch blended with suitable plasticizer(s).

The starch can be any plant starch (root and/grain starch), such as potato starch, sweet potato starch, corn starch, bracken starch, wheat starch, cassava starch, sago palm starch, rice starch, tapioca starch, soybean starch, arrow root starch, lotus starch, buckwheat starch or any mixture thereof.

In some embodiments, the TPS comprises a mixture of starch and glycerol in a ratio of 70:30.

Non-limiting examples of suitable plasticizers for the compositions and composite of the present invention include one or more of organophosphate compounds, phthalates and tartrate.

Suitable organophosphate compounds include tri-alkyl phosphate esters (such triethyl phosphate, trioctyl phosphate, etc.), tri-aryl phosphate esters, (such as tri-xylyl phosphate), alkyl diaryl phosphate esters (such as isodecyl diphenyl phosphate ester, 2-ethylhexyl diphenyl phosphate ester).

Suitable phthalates include alkly phthalates (such as dibutyl phthalate), aryl phthalate (such as diphenylphthalate). Suitable tartarates include alkyl tartrates (such as dibutyl tartrate).

Non-limiting examples of suitable flame retardant includes a halogen free phosphorous compound (such as melamine phosphate, ammonium phosphate, melamine polyphosphate and/or triphenyl phosphate, tricresylphosphate (TCP), tris(2-chloroethyl)phosphate (TCEP), tris(chloropropyl)phosphate (TCPP), tris(1,3-dichloro-2-propyl)phosphate (TDCPP), and tetrakis(2-chloroethyl)dichloroisopentyldiphosphate).

Non-limiting examples of suitable inorganic filler includes particulate (such as powdered, ground, etc.) limestone, calcium carbonate, clay and talc, diatomaceous earth, silica, bentonite clay, kaolin clay, and mica. The fillers can have particle size of about 5 micron to about 30 micron.

In some embodiments, the composition further comprises about 0.5-2% a colourant, such as mineral and/or dye. In some embodiments, the composition comprises about 1% colourant.

In some embodiments, the composition comprises:
about 60% by weight cellulose diacetate powder;
about 15% by weight triethyl phosphate;
about 15% by weight melamine phosphate;
about 5% by weight powdered limestone or diatomaceous earth;
about 5% by weight polybutylene adipate terephthalate (PBAT).

In some embodiments, the composition comprises:
about 60% by weight cellulose diacetate powder;
about 15% by weight triethyl phosphate;
about 15% by weight ammonium polyphosphate;
about 5% by weight powdered limestone or diatomaceous earth;
about 5% by weight polybutylene adipate terephthalate (PBAT).

In another aspect, the present invention provides a process of preparing the biodegradable composite of the present invention. The method comprises admixing cellulose alkanoate, polyester, plasticizer, flame-retardant and optionally inorganic filler, and heating the mixture to form a blended material/polymer blend, followed by compression molding the blended material with a fibrous reinforcement material to form the composite.

The blended material/polymer blend can be formed by batch mixing and/or extrusion mixing processes.

In some embodiments, the admixture is added to a batch mixer operated at a speed of about 80 to about 120 rpm, and the mixture is heated at about 150° C. to about 220° C.

In some embodiments, the admixture is extruded via a screw extruder with a screw speed of about 80-about 120 rpm, at a processing temperature of about 150° C. to about 220° C.

In some embodiments, the blend is granulated for compression molding. In some embodiments, the compression molding is conducted at a temperature about 150° C. to about 220° C.

In some embodiments, the process comprises initiating the compression molding with no added pressure to allow the polymer blend to melt, followed by application of a pressure intermittently.

In some embodiments, the composite material is formed by sandwiching the granulated blend between two layers of woven reinforcement material.

In some embodiments, the composite material is formed by sandwiching one or more layers of the woven reinforcement material between two layers of granulated blend.

In some embodiments, the fibrous reinforcement material is pretreated to render the material hydrophobic prior to the compression molding, for example by treating the material with a 10-20% solution of methyl methacrylate or sodium hydroxide, followed by drying the material.

To gain a better understanding of the invention described herein, the following examples are set forth with reference to the accompanying drawings. It will be understood that these examples are intended to describe illustrative embodiments of the invention and are not intended to limit the scope of the invention in any way.

### EXAMPLES

### Example 1: Pretreatment of Hemp Fabric

Hemp fabric (moisture content, >1.0 wt. %) was pretreated by submersion in a 20% aqueous solution of sodium hydroxide for 6 hours. After the submersion step, the fabric was rinsed with deionized water and dried in an oven at 70° C. for 24 hours.

### Example 2: Preparation of a Biodegradable Composite:from a Composition Comprising the Following Components

about 60% by weight cellulose diacetate powder;
about 15% by weight triethyl phosphate;
about 15% by weight melamine phosphate;
about 5% by weight powdered limestone;
about 5% by weight polybutylene adipate terephthalate (PBAT).

All components were admixed together in a beaker before introducing the admixture to the preheated batch mixer. Batch mixing of the components was carried out using a Thermo Haake Rheomix 3000 with roller-rotors at 80 RPM at temperature of about 210° C. to form a blended material. The admixture was added over a span of 1 minute and left to mix for a total of 30 minutes. Once cooled, the blended material was ground into 3 mm particles using a SRE 66 Rapid granulator. Plaques of the blended material were made using a custom-built compression mold of the desired size and shape, The plaques were formed in the mold using a hot press (Carver Press model 4122) with a custom set-up for rapid cooling. Polymer blend in the form of granules was added to the compression mold, followed by the reinforcement fabric and more granules on top to make a sandwich composite. Prior to application of pressure, the polymer blend and the reinforcement fabric are heated to 200° C. for 10 minutes at zero pressure to allow the polymer blend to melt, followed by the application of 2 tons of pressure for 2 minutes. The pressure is then released to zero pressure to relieve stress, followed by the reapplication of 6 tons of pressure for 2 minutes. The mold was rapidly cooled to 80° C. keeping the pressure constant at 6 tons. Thickness of the sample is about 3.5 mm.

Having reached room temperature, individual rectangular samples of 10 cm long by 1.3 cm wide were cut from the molded sample using a sharp cutter. The samples were preconditioned in an oven at 70° C. for 170 hours and subsequently put in a desiccator at room temperature for 4 hours (as required by the UL 94 flammability standard).

### Example 3: Testing of Composite Prepared Using Process of Example 2

A total of three rectangular samples were used for the vertical burning test (UL 94 standard) to classify them as either V-0, V-1 or V-2.

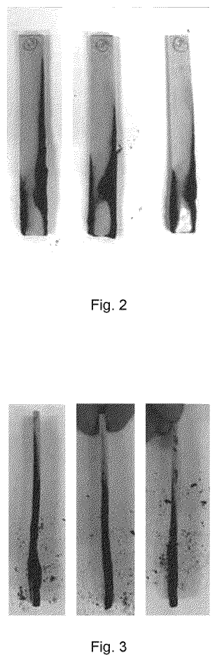

FIG. 2 is a photograph showing the test specimens formed from molded composite material and one layer of hemp fabric prepared using the process of Example 2, after a 50 W vertical burn test (front view).

FIG. 3 is a photograph showing the test specimens formed from molded composite material and one layer of hemp fabric prepared using the process of Example 2, after a 50 W vertical burn test (side view).

As shown in Table 1, three composite bar replicates were characterized according to the following parameters:
Afterflame (t₁): The time in seconds that a flame persisted after the ignition source is removed following the initial 10 second burn.
Afterflame (t₂): The tine in seconds that a flame persisted after the ignition source is removed following the second 10 second burn.
Afterglow (t₃): The time in seconds that a combustion glow persisted after Afterflame (t₂) extinguished.
Burned to Clamp: Whether the specimen burned to the holding clamp placed 6 mm from the top of the bar specimen.
Did Material Drip: Whether the material became molten and dripped on the cotton placed below the burner.
Did the Cotton Ignite: Whether the cotton placed below the burner ignited on contact with dripping material.

Results of the flammability vertical test for the previously described samples are summarized in Table 1 below:

TABLE 1
Vertical Flammability Results of the Developed Biocomposite Batches

| | | | | | Burned | Did | Did |
|---|---|---|---|---|---|---|---|
| | Afterflame | Afterflame | Afterglow | | to | material | cotton |
| Replicate | t₁ (s) | t₂ (s) | t₃ (s) | t₂ + t₃ (s) | clamp? | drip? | ignite? |
| 1 | 0 | 17 | 0 | 17 | No | No | No |
| 2 | 23 | 6 | 0 | 6 | No | No | No |
| 3 | 2 | 10 | 0 | 10 | No | No | No |

According to V-0 and V-1 classification (UL 94 flammability standard) all samples must stop burning within 10 seconds or 30 seconds respectively on a vertical sample allowing for drops of plastic material that are not in flames. All replicates in this example fall within either V-0 or V-1 classification.

### Example 4: Preparation of Thick Biodegradable Composite

Batch mixing was carried out using the same process as in Example 2. All materials were dry blended together in a beaker before adding to the preheated batch mixer. The specific biodegradable composition comprises:
about 60% by weight cellulose diacetate powder;
about 15% by weight triethyl phosphate;
about 15% by weight melamine phosphate;
about 5% by weight limestone;
about 5% by weight polybutylene adipate terephthalate (PBAT).

Plaques of the blend were made in the same manner as in example 2, but in this case a final thickness of 6 mm was kept. Individual rectangular samples of 12.5 cm long by 1.3 cm wide were made using a sharp cutter. The samples were preconditioned at 25° C. and 50% relative humidity for 48 hours (as required by the UL 94 standard for flammability of plastic parts in devices and appliances).

### Example 5 Testing of Composite Prepared Using Process of Example 4

After the pre-conditioning step, the samples obtained in Example 4 were arbitrarily divided into two sets of five samples each. The second set of samples was only to be tested if there were any inconsistencies in the results from the first set. Results of the flammability vertical test for the previously described samples are summarized in Table 2 below:

TABLE 2
Vertical Flammability Results of the Developed Biocomposite Batches

| | | | | | Burned | Did | Did |
|---|---|---|---|---|---|---|---|
| | Afterflame | Afterflame | Afterglow | | to | material | cotton |
| Replicate | t₁ (s) | t₂ (s) | t₃ (s) | t₂ + t₃ (s) | clamp? | drip? | ignite? |
| 1 | 0 | 0 | 0 | 0 | No | No | No |
| 2 | 0 | 0 | 0 | 0 | No | No | No |
| 3 | 0 | 0 | 0 | 0 | No | No | No |
| 4 | 0 | 0 | 0 | 0 | No | No | No |
| 5 | 0 | 0 | 0 | 0 | No | No | No |

According to V-0 classification (UL 94 flammability standard) all samples must stop burning within 10 seconds on a vertical sample allowing for drops of plastic material that are not in flames. All replicates in this example fall within V-0 classification.

### Example 6: Preparation of Thin Biodegradable Composite

Batch mixing was carried out in a similar manner to Example 2, but the temperature was kept at 130° C. during mixing. All materials were dry blended together in a beaker before adding to the preheated batch mixer. The specific biodegradable composition comprises:
about 60% by weight cellulose diacetate powder;
about 15% by weight triethyl phosphate;
about 15% by weight ammonium polyphosphate;
about 5% by weight limestone;
about 5% by weight polybutylene adipate terephthalate (PBAT).

Plaques of the blend were made in a similar manner to Example 2, but the temperature was kept at 160° C. during molding. Samples with a final thickness of less than 1 mm could be obtained in this way.

### Example 7: Preparation of Thin Biodegradable Composite

This sample was prepared in the same manner as example 6. The specific biodegradable composition comprises:
about 60% by weight cellulose diacetate powder;
about 15% by weight triethyl phosphate;
about 15% by weight ammonium polyphosphate;
about 5% by weight diatomaceous earth;
about 5% by weight polybutylene adipate terephthalate (PBAT).

Plaques were prepared in the same manner as Example 4. Samples with a final thickness of less than 1 mm could be obtained in this way.

### CITED REFERENCES

1. Zeng, X., Yang, C., Chiang, J. F. and Li, J. Innovative e-waste management: From macroscopic to microscopic scales. Science of The Total Environment, 2017. 575: p. 1.
2. Heacock, M., et al., E-waste and harm to vulnerable populations: A growing global problem. Environmental Health Prerspective, 2016. 124: p. 550.
3. Chen, A. M., Dietrich, K. N., Huo, X. and Ho, S. M. Developmental Neurotoxicants in E-waste: An emerging health concern. Environmental Health Prerspective, 2011. 119: p. 431.
4. Workshop Materials on WEEE Management in Taiwan. Environmental Protection Agency (EPA). October 2012.
5. Jambeck, J. R., et al., Plastic waste inputs from land into the ocean. Science, 2015. 347 (6223): p. 768-771.
6. Liu, J., et al., Future paper based printed circuit boards for green electronics. Energy and Environmental Science, 2014. 7: p. 3674.
7. Siegel, A. C., et al., Foldable printed circuit boards on paper substrates. Advanced Functional Materials, 2009. 20: p. 28.

1. A biodegradable composite material comprising:
a) a polymeric matrix comprising:
about 50 to 80% by weight of a cellulose alkanoate;
about 0.1 to 10% by weight of a polyester, wherein the polyester is an aliphatic-aromatic copolyester, an aliphatic polyester, or a mixture of an aliphatic polyester and thermoplastic starch;
about 10 to 30% by weight of a plasticizer;
about 10 to 20% by weight of a flame-retardant component;
optionally 0.1 to 10% of an inorganic filler; and
b) a fibrous reinforcement material.

2. The composite material of claim 1, wherein the cellulose alkanoate is cellulose acetate, cellulose diacetate or cellulose triacetate.

3. The composite material of claim 1 or 2, wherein the aliphatic-aromatic copolyester is polybutylene adipate terephthalate (PBAT).

4. The composite material of claim 1 or 2, wherein the aliphatic polyester is polybutylene succinate (PBS), polylactic acid (PLA), and/or polyhydroxyalkanoates (PHA).

5. The composite material of any one of claims 1 to 4, wherein the plasticizer is an organophosphate compound, a phthalate and/or a tartrate.

6. The composite material of claim 5, wherein the organophosphate compound is triethyl phosphate.

7. The composite material of any one of claims 1 to 6, wherein the flame retardant is a halogen free phosphorous compound.

8. The composite material of claim 7, wherein the halogen free phosphorous compound is melamine phosphate or ammonium polyphosphate.

9. The composite material of any one of claims 1 to 8, wherein the inorganic filler is powdered limestone or diatomaceous earth.

10. The composite material of any one of claims 1 to 9, wherein the reinforcement material comprises one or more layers of a woven fabric made of natural fibers.

11. The composite material of claim 10, wherein the woven fabric has been pre-treated to render the material hydrophobic.

12. The composite material of any one of claims 1 to 11, for use as an insulating material in printed circuit boards (PCB).

13. A process for preparing a composite material of any one of claims 1 to 11, comprising:
a) admixing the cellulose alkanoate, the polyester, the plasticizer, the flame retardant, and optionally the inorganic filler;
b) heating the admixture to form a blended material; and
c) compression molding the blended material with the reinforcement material.

14. The process of claim 13, wherein the admixture is added to a batch mixer at a speed of about 80-about 120 rpm, and the admixture is heated at about 150° to about 220° C.

15. The process of claim 13, wherein the admixture is extruded via a screw extruder with a screw speed of about 80-about 120 rpm, at a processing temperature of about 150° to about 220° C.

16. The process of any one of claims 13 to 15, further comprising granulating the blended material prior to compression molding.

17. The process of any one of claims 13 to 16, wherein the compression molding is conducted at a temperature about 150° to about 220° C.

18. The process of any one of claims 13 to 17, which comprises melting the blended material, followed by intermittent application of a pressure.

19. The process of any one of claims 16 to 18, wherein the compression molding comprises sandwiching one or more layers of the woven reinforcement material between two layers of granulated blended material.

20. A biodegradable composition comprising:
about 50-80% by weight of a cellulose alkanoate,
about 0.1 to 10% by weight of a polyester, wherein the polyester is an aliphatic-aromatic copolyester, an aliphatic polyester, or a mixture of an aliphatic polyester and thermoplastic starch;
about 10 to 30% by weight of a plasticizer;
about 10 to 20% by weight of a flame-retardant component; and
optionally an inorganic filler.

21. The composition of claim 20, wherein the cellulose alkanoate is cellulose acetate, cellulose diacetate or cellulose triacetate.

22. The composition of claim 20 or 21, wherein the aliphatic-aromatic copolyester is polybutylene adipate terephthalate (PBAT).

23. The composition of claim 20 or 21, wherein the aliphatic polyester is polybutylene succinate (PBS), polylactic acid (PLA), and/or polyhydroxyalkanoates (PHA).

24. The composition of any one of claims 20 to 23, wherein the plasticizer is an organophosphate compound, a phthalate and/or a tartrate.

25. The composition of claim 24, wherein the organophosphate compound is triethyl phosphate.

26. The composition of any one of claims 20 to 25, wherein the flame retardant is a halogen free phosphorous compound.

27. The composition of claim 26, wherein the halogen free phosphorous compound is melamine phosphate or ammonium polyphosphate.

28. The composition of any one of claims 20 to 27, wherein the inorganic filler is powdered limestone or diatomaceous earth.
